(19) United States
(12) Patent Application Publication
(10) Pub. No.: US 2014/0214345 A1
(43) Pub. Date: Jul. 31, 2014

(54) SYSTEM AND METHOD FOR MONITORING AN ELECTRICAL NETWORK

(71) Applicant: Michael ORDANIS, Pickering (CA)

(72) Inventor: Michael ORDANIS, Pickering (CA)

(21) Appl. No.: 13/749,896

(22) Filed: Jan. 25, 2013

(51) Int. Cl. G01R 22/06

(52) U.S. Cl. CPC G01R 22/063
USPC 702/62

(57) ABSTRACT

An energy monitoring system which in preferred embodiments employs at least one nodal junction receiving and creating data by analog to digital conversion from a plurality of local node sensors. Data accumulated by the nodal junction is used for analysis of wave patterns to detect anomalies in the local electrical network and/or loads connected to the local electrical network. Anomalies can be detected in various ways, including: comparison of data with historical data acquired from the local node sensors; comparison of data with known wave pattern profiles for similar loads; and comparison of data with data acquired from local node sensors at other locations. Thus, the accumulation of data in the system of the invention provides the ability to perform comparative analysis to a baseline or standard, and also the ability to perform comparative analysis at an enterprise level across different target locations.

### FIELD OF THE INVENTION

This invention relates to an energy monitoring systems for measuring and recording the electrical energy consumed by one or more loads.

### BACKGROUND OF THE INVENTION

It is well known in the art that devices can be made to measure and record the electrical energy used by a load and some of these devices with further enhancements can be made to measure and record the current harmonics created by the load. There are a number of patents which reveal devices which can measure the energy consumption and current harmonics of loads, both individual and grouped. These prior art devices are bulky, expensive and tend to be limited with respect to the number of loads that can be monitored by a single device, frequently requiring considerable expertise in their implementation and use. Many of these prior art devices are only able to measure just total electrical energy, total gas or total water consumed at the premises.

### BRIEF DESCRIPTION OF THE DRAWINGS

In drawings which illustrate by way of example only a preferred embodiment of the invention,

FIG. 1a is a schematic view of a first system according to the invention.

FIG. 1b is a schematic view of a further system according to the invention.

FIG. 2 is a schematic view of one embodiment of a nodal junction according to the invention.

FIG. 3 is a schematic view of a further system according to the invention.

FIG. 4 is a schematic view of a further system according to the invention.

FIG. 5 is a schematic view of a further embodiment of a nodal junction according to the invention.

### DETAILED DESCRIPTION OF THE INVENTION

The invention provides an energy monitoring system which in preferred embodiments employs at least one nodal junction 20 receiving data in the form of current signals from a plurality of local node sensors 12. The current signals generated by local node sensors are either alternating current (AC) or direct current (DC) and are typically in the 0-80 mA range, which are converted to millivolt levels and then sampled by an analog to digital converter (ADC) contained within the nodal junction to create data points for further analysis. Examples of AC sensors include current transformers (CT) to measure current and potential transformers (PT) to measure voltage. Examples of DC sensors include gas and water volume pulse generators, pressure sensors, temperature sensors, airflow sensors and CO2 level sensors. Data accumulated by the nodal junction is used for analysis of wave patterns to detect anomalies in the local electrical network and/or loads 2 connected to the local electrical network. Anomalies can be detected in various ways, including: comparison of data with historical data acquired from the local node sensors; comparison of data with known wave pattern profiles for similar loads 2; and comparison of data with data acquired by local node sensors at other locations. Thus, the accumulation of data in the system of the invention provides the ability to perform comparative analysis to an historical profile, or to a baseline or standard developed from known wave pattern profiles for similar loads 2; comparison of data with known wave pattern profiles published as regulatory or standards data for profiles with similar loads; and/or networks; and also the ability to perform comparative analysis at an enterprise level across different target locations.

Any AC powered electrical device or circuit when in use or operation generates a “field harmonic”, or wave pattern. The wave pattern is more pronounced in nonlinear loads (i.e. loads that draw current with a waveform that is not the same as the waveform of the supply voltage). Examples of non-linear loads include: Welding machines, arc furnaces, induction furnaces, rectifiers, variable-speed drives for asynchronous or DC motors, UPSs, computers, photocopy machines, fax machines, television sets, microwave ovens, fluorescent lighting, LED lighting and devices involving magnetic saturation such as transformers. The negative effects of certain waveforms can be (a) increases in energy costs and (b) premature aging of equipment. The present invention employs local node sensors to collect data from any electrical device or circuit connected to individual breakers at the target location and communicates the data, via telemetry transmission, to a collection server in order to calculate a “Fast Fourier Transform” (FFT) that will establish the wave pattern or field harmonic for the specific load 2 or circuit from which the data has been collected.

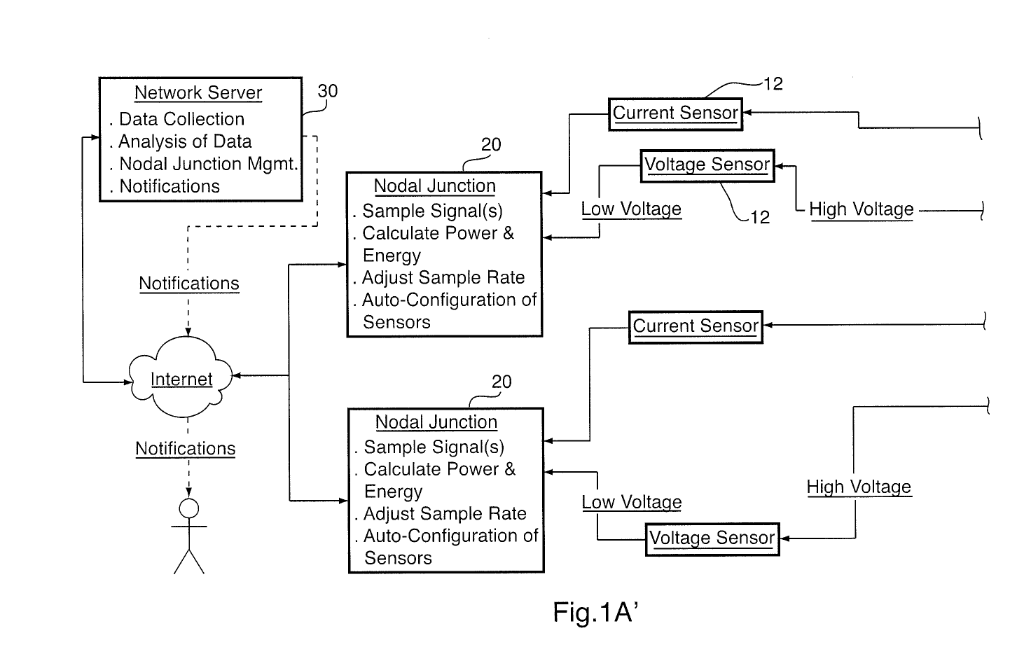

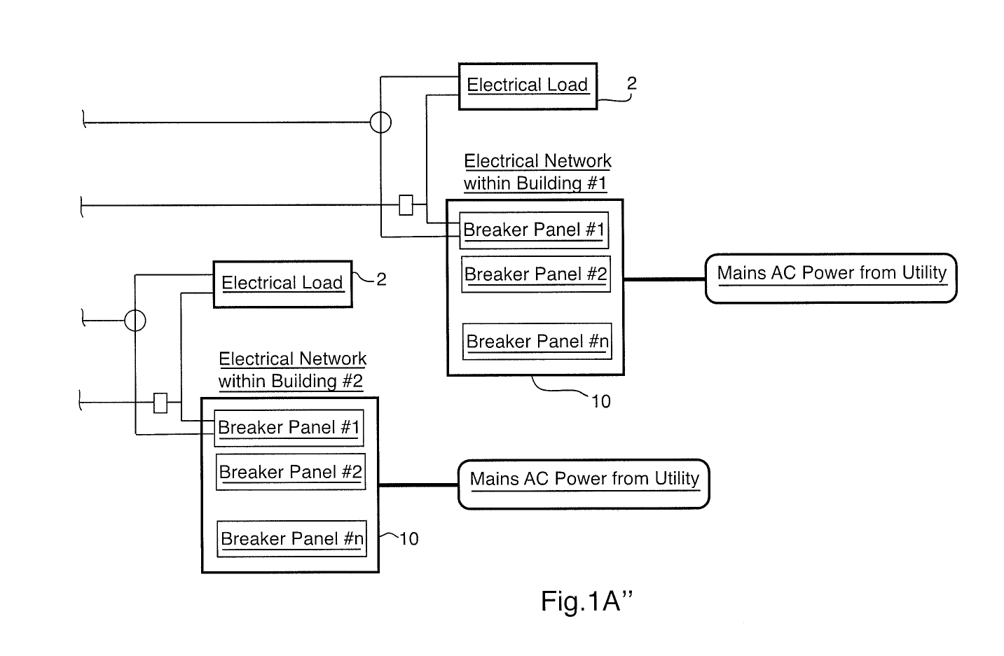

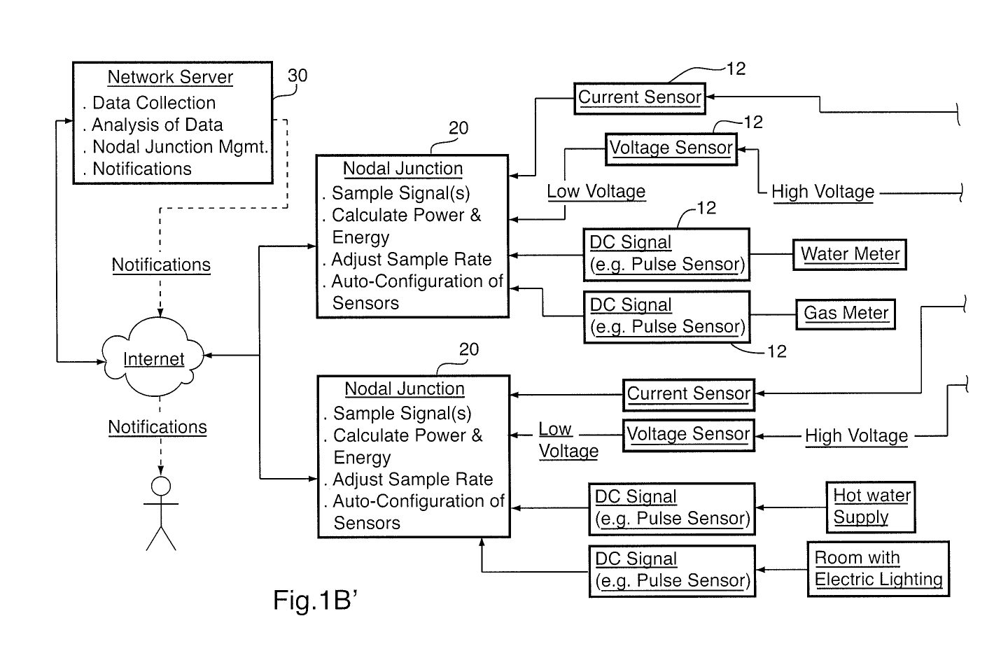

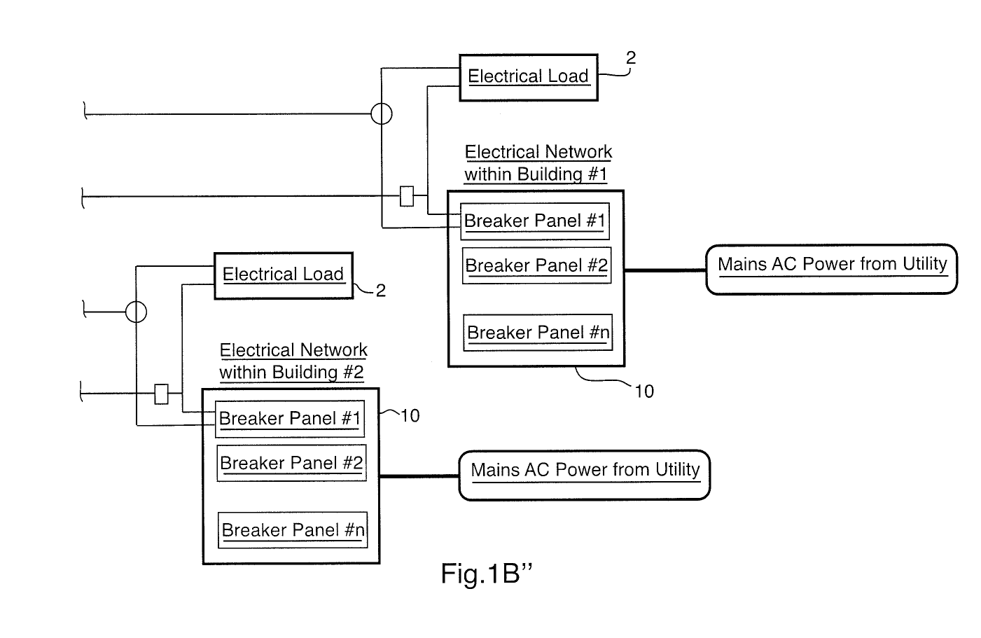

FIG. 1 illustrates a system according to the present invention, by way of example, showing two target locations 10 of a potentially unlimited number of target locations. The continuous collection of telemetry data by this system over time, and in the preferred embodiments over different locations, allows for a comparative analysis of wave patterns to detect anomalies.

In one preferred embodiment, prior to installation of the system of the invention at a target location a baseline FFT pattern for operation standards for the electrical network can be established based on other locations having a similar network and/or comparable loads 2 and circuits, or on specific loads 2 in a circuit. An FFT pattern established based on electrical network and load 2 operation can be compared to this standard or baseline in ongoing sampling during operations, to detect anomalies in a load 2 and/or circuit. Such anomalies can be detected prior to an actual fault condition, thus providing the end user with dynamic analysis for preventative maintenance of loads 2 and electrical circuits, as well as ongoing analysis that can allow an end user to optimize loads 2 and circuits to improve efficiency and electrical consumption levels.

For example, an air handling unit with bad or worn bearings, belts or pulley on its blade assembly will require greater power consumption or a power surge to move the blade to a desired RPM level. The FFT comparison of real-time data from the faulty air conditioner with data acquired from a similar model or capacity of air conditioner will show a spike or electrical surge or variation in the wave pattern which can be analyzed and corrective action taken. Similarly, in a compressor or pump with worn seals o r valve s the motor must work harder or for a longer time to maintain pressure against loss through the seals. The change of FFT from the known baseline or standard would be indicated in the wave pattern, and corrective action and/or a more detailed analysis of the problem load 2 can be initiated.

In an example involving a circuit, a simple electrical outlet or branch circuit with multiple outlets which is overloaded, for example with multiple power bars connected to loads 2, would show an increase or surge in load 2 levels as the electrical devices connected to the power bars are activated. Such devices may be able to operate on lower power setting, and as such would not cause the circuit breaker to trip; but as the connected devices need more power, surges to the limit of the circuit will be indicated in the FFT pattern as power spikes, even if the duration of the spikes is too short to trip the breaker. Comparative analysis of FFT wave patterns—either with historical patterns from that location or with baseline standards set by data accumulated from a number of locations—will show the spikes and action can take to correct the overload on the outlet and associated circuit.

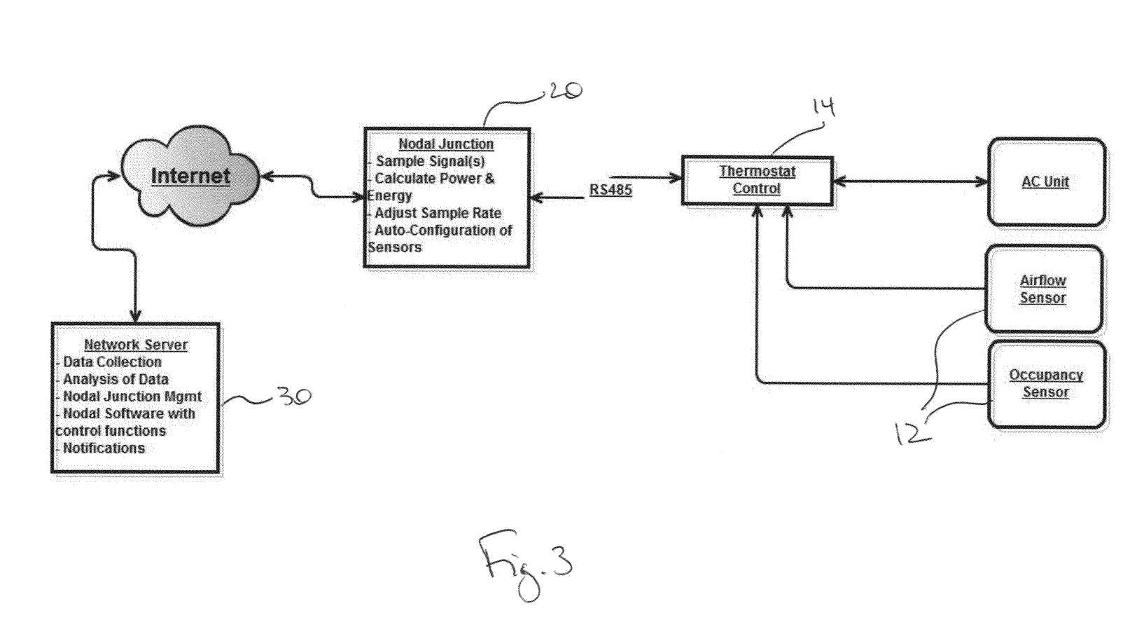

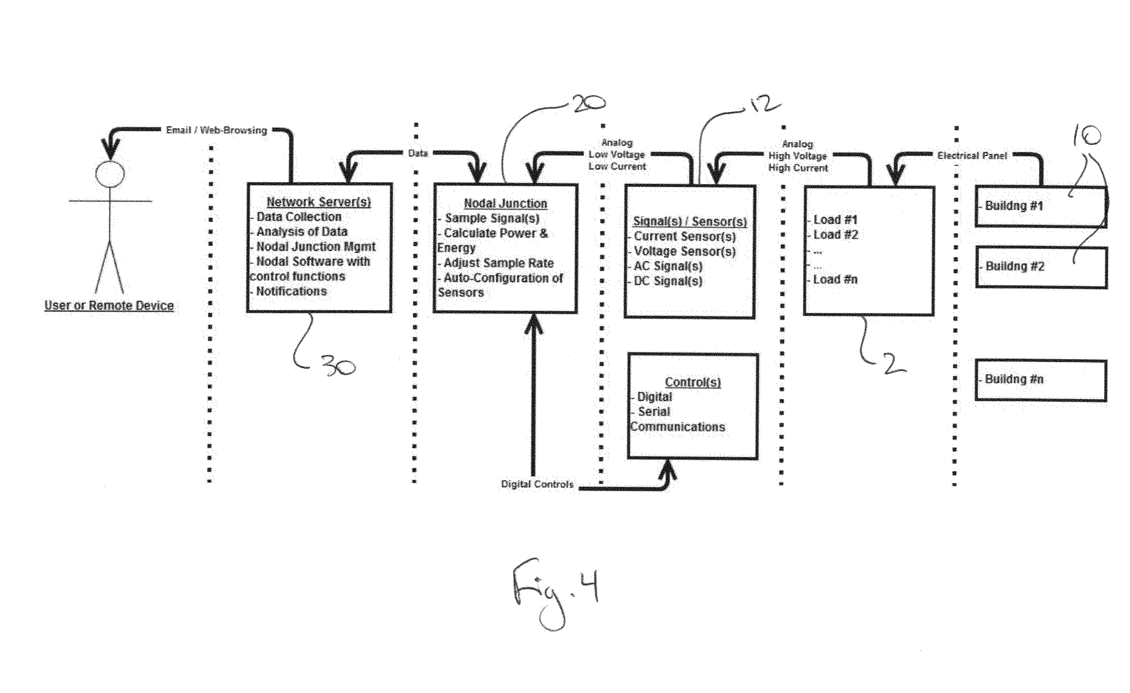

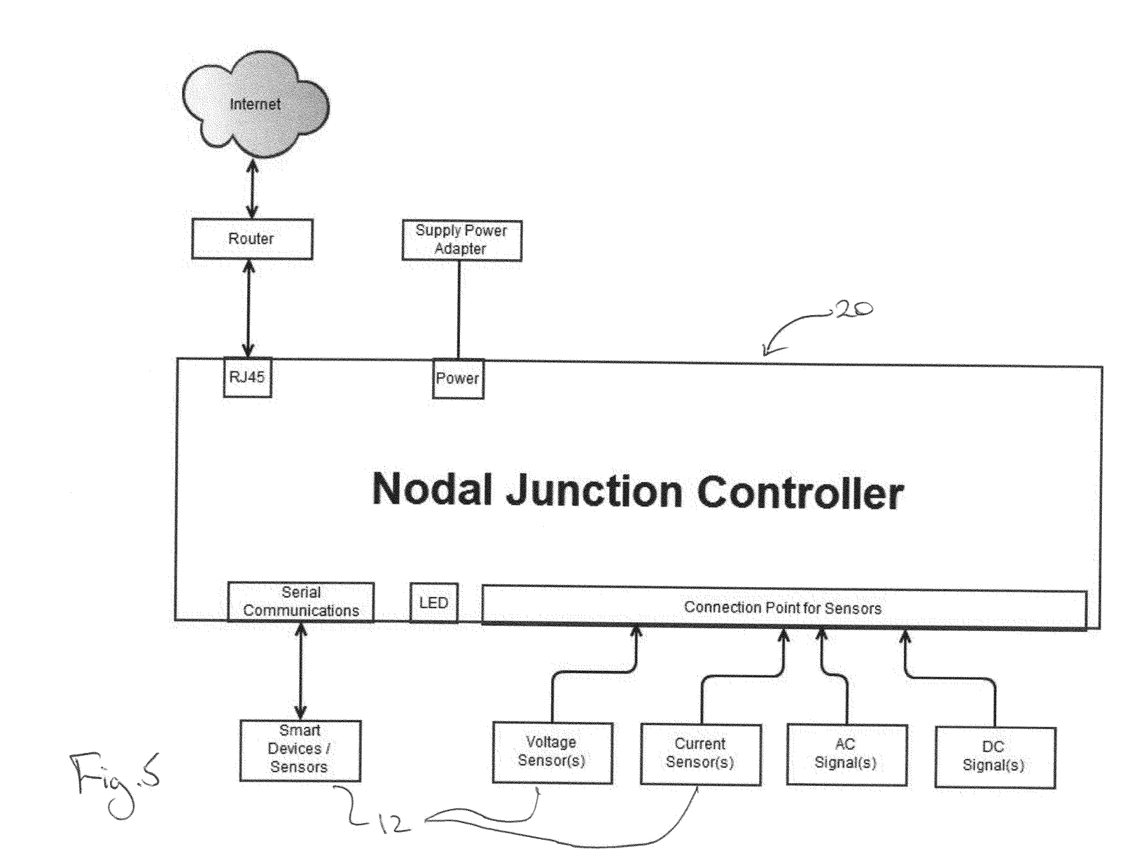

The basic system comprises at least one node sensor 12, preferably a plurality of node sensors 12 as shown, disposed at the target location 10. The node sensors 12 may for example include any number of electrical sensors, heat sensors, vibration sensors and/or pulse sensors, depending upon the particular network or equipment being monitored. For example, electrical sensors such as current sensors and voltage sensors may be used to monitor circuits in the electrical network; heat sensors can be used to monitor motorized devices and other devices which might be subject to overheating due to a malfunction, heating systems, furnaces and the like; vibration sensors can be used to monitor compressors, motorized devices and other devices which have reciprocating or rotational components that produce a consistent vibration pattern, as shown in FIG. 3; and pulse sensors may be used to monitor pulse signals from incremental counters for measuring, for example, gas feed for heating/air conditioning or other gas-fed devices, and air flow and/or water flow rates, as shown in FIG. 3.

In the preferred embodiments the node sensors 12 are linked with a nodal junction 20 communicating the data acquired from the node sensors 12 to a data processing device such as a server 30, to thus capture all the reported data (including FFT input data) and store it on the server 30. The end user analysis is performed at the server 30, which contains the comparative data (historical, baseline, etc. as available).

In the preferred embodiment the nodal junction 20 is programmable, and can be programmed by the server 30 dynamically to extract specific select data points, and/or control all local node sensors 12 to extract (or filter) selected information. The nodal junction 20 consolidates the data from the various node sensors 12, thus greatly reducing bandwidth requirements, and transmits the data to the server 30 (which in turn may consolidate data from multiple nodal junctions 20). Preferably where the nodal junction 20 is dynamically programmed for specific data collection, it can also isolate any of the local node sensors 12 at the target location to collect specific data points different from the other local node sensors 12.

When the server 30 receives and records the collected data, it can function in a single-user or customer mode, or can perform analysis across an entire enterprise network. This provides a comparative profile over a large number of like networks and/or loads 2, which benefits users because the larger data pool provides profiles for a greater variety of networks and loads 2, and more data from which to establish norms and baselines within each category of network and load 2. Thus, in one embodiment users can “opt in” to participate in data-sharing based on the pool of data acquired from all users of the system, for the benefit of all participating users.

Thus, the comparative analysis can be performed not just on end user data, but on all of the enterprise (or all users') data points. In this fashion an anomaly can be detected via an historical comparison, but also by comparison to all circuits across the enterprise for each data point for like devices. This enables full enterprise data collection and analysis in the preferred embodiments of the invention, and thus allows each user to benefit from other installations connected to the enterprise server.

By analysis of FFT wave patterns, the server 30 can indicate a fault condition by initiating warnings or alarms before equipment being monitored reaches a fail-point or an inefficient mode of operation, by comparison to a standard or baseline which allows the server 30 to detect anomalous behaviour from any load 2 or circuit. This provides an opportunity for preventative analysis and action (as opposed to post-hoc fail-point analysis). In the preferred embodiments this function is robust and flexible, so that warning parameters or anomaly range selection can be entered by the user or system administrator, and changes at any time and the nodal junction 20 and local node sensors 12 at the target location can be dynamically modified for the newly selected ranges.

The node sensors 12 would typically be sampled at standard sampling rates (e.g. 3 to 4 ksps), and from the sampling of electrical performance in loads 2 and circuits are able to collect the necessary component information to be analyzed through an FFT and the resultant wave pattern. Preferably each node sensor 12 has the capability of sampling at a much higher sampling rate in specific situations, the nodal junction 20 being capable of dynamically increasing (or decreasing) the sampling rate of one or more node sensors 12 as needed to allow for flexible analysis and patterning of a given electrical circuit or device. The node sensors 12, being distributed about the target location 10, monitor many electrical circuits and loads 2 and provide data from each for FFT analysis.

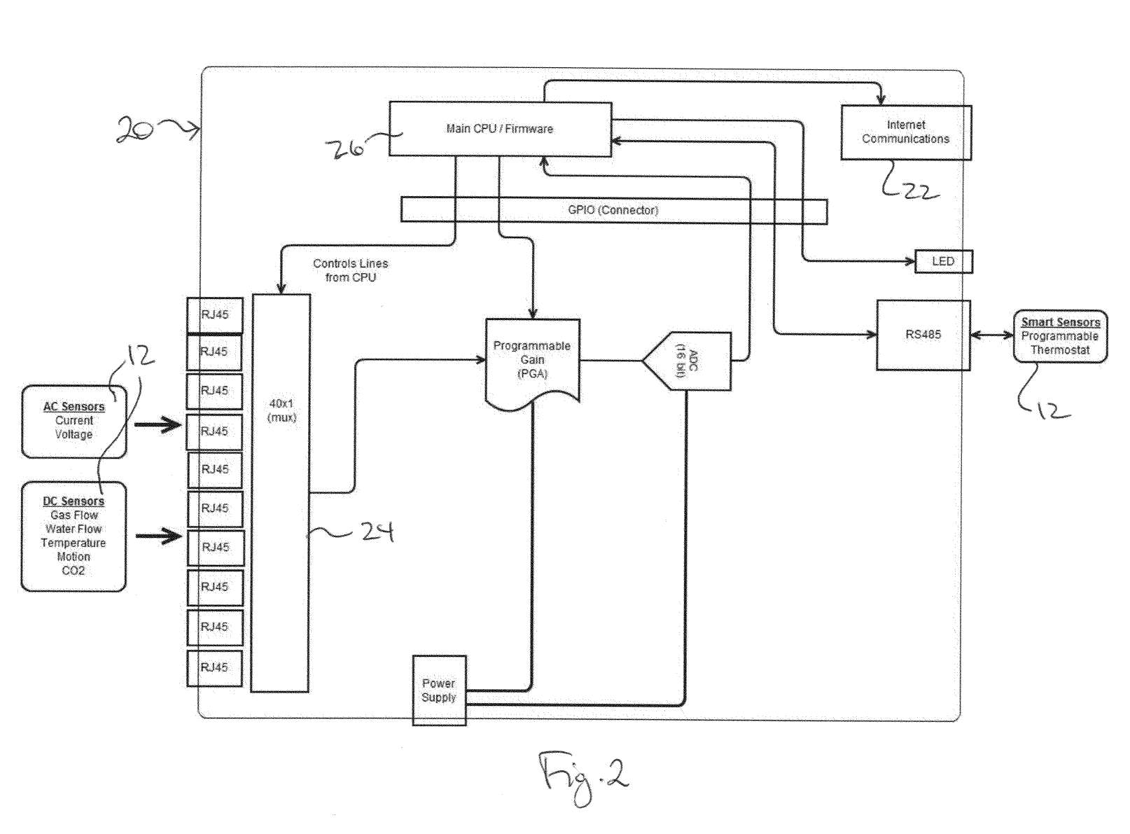

The nodal junction 20, illustrated in FIG. 2, is a collection point for data sampled from the local node sensors 12. The nodal junction 20 collects information from local node sensors 12, preferably for multiple services (for example electrical, water and gas), and passes the accumulated sensor information, to the network sever 30 for data storage and analysis. The nodal junctions 20 are preferably capable of collecting information from multiple local node sensors 12, for example through multiplexer 24, and accumulating the data into a single packet or small numb e r of packets for transmission to the server 30 via communications module 22, for example over the Internet as shown in FIG. 1, thus reducing the total bandwidth required to transfer data from multiple collection points.

The nodal junctions 20 can be stacked into an array, as shown in FIG. 1, thus handling a greater number of local node sensors 12 and concentrating the accumulated data for the server 30. The nodal junction 20 preferably has flexible firmware control resident in CPU 26 which, based on data received and analyzed, can be dynamically changed by the server 30. Examples of dynamic changes are: sampling rates on any given local node sensor 12 can be changed for a more thorough or comparative analysis; and values of the various gain stages can be fine tuned to compensate for aging components in the signal chain.

While the server 30 captures and archives historical information from all (active) node sensors 12 and nodal junctions 20, in the monitoring of electrical equipment, heating, air conditioning, generators and other such devices in any given environment, maintaining an accurate history is useful for comparative or spot curve analysis, and can be used to isolate specific equipment or to look at the environment at the target location 10 as a whole. The application software residing in the server 30 is preferably designed to provide the user with detailed information on all devices within a specific environment, while at the same time providing the user with the flexibility to isolate specific devices or time slices in that environment. Such flexible application software is designed to provide the user with detailed information while at the same time providing the greatest flexibility.

The architecture of the overall system is thus a server-controlled information service, which can be applied to some or all metered devices in any target location 10, effectively serving as a ‘top down’ control system to provide the end user maximum flexibility and control to monitor all loads 2 and circuits being monitored in the target location or any portion thereof In some embodiments the server 30, or the nodal junction 20, may provide control signals to adjust the environment at the target location 10, for example as shown in FIG. 3 in which the thermostat 14 monitoring ambient air temperature can be configured and/or controlled by the server 30 (via the nodal junction 20) to adjust the air temperature in response to a deviation outside an acceptable range.

When the system is set up a standard for monitored devices or benchmark may set, providing the server with a baseline on which to base its programmed analysis. As the server collects data for analysis, it can automatically compare selected data with a benchmark value established by the baseline, and if the data does not match the benchmark (within a user-selected range or allowable deviation), the system can be programmed to notify the user by alert (for example, a text message or email), of the variance or anomaly detected so the user can take immediate corrective action.

Various embodiments of the present invention having been thus described in detail by way of example, it will be apparent to those skilled in the art that variations and modifications may be made without departing from the invention. The invention includes all such variations and modifications as fall within the scope of the appended claims.

We claim:

1. An electric harmonic monitoring system for measuring a periodic waveform representing an aggregation of fundamental and harmonic components of at least one electrical load with at least two conductors, the system comprising:
at least one current sensor for detecting a level of current flowing in at least one of the load conductors comprising an inductor having at least one complete electrical turn in inductive communication with the load conductor,
at least one nodal junction controller, the nodal junction controller configured to measure the level of current of each connected current sensor at a rate of at least one measurement per cycle, and transmitting the measurements via a network connection to at least one network server, and
the at least one network server configured to receive, store and analyze at least one finite set of measurements from at least one nodal junction controller, having FFT algorithms for converting the list of measurements into a set of coefficients of a finite combination for sinusoids thus determining the fundamental and harmonic components of the received measurements, and having algorithms for detecting meaningful variations in the list of coefficients and the ability to notify personnel of such variations.
